(19) United States
(12) Patent Application Publication
(10) Pub. No.: US 2021/0076504 A1
(43) Pub. Date: Mar. 11, 2021

(54) DOUBLE-SIDED ASSEMBLY ON FLEXIBLE SUBSTRATES

(71) Applicant: Molex, LLC, Lisle, IL (US)

(72) Inventors: Michael DEPPE, Lisle, IL (US); Matthew SHANNON, Lisle, IL (US); Steve R. MOSER, Lisle, IL (US)

(73) Assignee: Molex, LLC, Lisle, IL (US)

(21) Appl. No.: 16/955,771

(22) PCT Filed: Dec. 20, 2018
(86) PCT No.: PCT/US2018/066684

§ 371 Date: Jun. 19, 2020

Related U.S. Application Data
(60) Provisional application No. 62/609,339, filed on Dec. 22, 2017.

(51) Int. Cl. H05K 3/32; H05K 3/12; H05K 1/18; H05K 1/11

(52) U.S. Cl. CPC H05K 3/321; H05K 3/12; H05K 1/189; H05K 1/118; H05K 3/284; H05K 2203/0173; H05K 2203/1572; H05K 2203/1563; H05K 2203/1476; H05K 2203/0165

(57) ABSTRACT

A method for creating a circuit assembly includes printing first conductive traces on a first side of a flexible substrate, printing second conductive traces on a second side of the flexible substrate opposite to the first side, and placing the flexible substrate on a first pallet with the first side facing up. The method includes printing conductive adhesive to form first contact pads on the first side, placing at least one first component onto the first contact pads, and removing the flexible substrate from the first pallet. The method includes placing the flexible substrate on a second pallet with the second side facing up, where the second pallet includes recessed areas or cut outs that align with the at least one first component, printing conductive adhesive to form second contact pads on the second side, and placing at least one second component onto the second contact pads.

### CROSS-REFERENCE TO RELATED APPLICATIONS

This application claims the benefit under 35 U.S.C. § 119(e) of the filing date of U.S. Provisional Patent Application No. 62/609,339, for “DOUBLE-SIDED ASSEMBLY ON FLEXIBLE SUBSTRATES” which was filed on Dec. 22, 2017, and which is incorporated here by reference.

### TECHNICAL FIELD

This disclosure relates to the field of electronic circuits, and more specifically to flexible substrate circuits.

### DESCRIPTION OF RELATED ART

Electronic circuits are conventionally fabricated by mounting circuit elements and integrated circuit packages on circuit boards. The boards electrically interconnect the various passive and active circuit elements and integrated circuit packages into one or more functional units. In particular, flexible printed circuit boards (PCB) have a wide variety of applications due to their low cost, flexibility and versatility. For instance, flexible printed circuit boards may be used in areas where space is limited, or where the surfaces upon which the printed circuits are mounted are not flat. Further, flexible printed circuit boards may be useful in dynamic applications, where the board is subjected to repeated flexing throughout its life, such as in disk drive heads, printer heads, and display board interconnects for portable computers.

Printed electronics and flexible hybrid electronics (FHE) are emerging technologies that integrate additive printing technologies (e.g., screen printing, flexographic printing, inkjet printing, or other additive deposition techniques) with traditional packaged components. Progress has been made on single-sided assembly of packaged electrical components on additively printed conductors formed on flexible substrates, however, the ability to attach components to additively deposited conductors on both sides of the flexible substrate has not been demonstrated in industry. While rigid printed circuit boards (PCBs) and copper-flex circuit boards (Cu-Flex) are mature technologies that include double-sided component attach, double-sided attachment still remains elusive for HIE technology.

### SUMMARY

In one aspect, a method for creating a circuit assembly includes printing first conductive traces on a first side of a flexible substrate, printing second conductive traces on a second side of the flexible substrate opposite to the first side, and placing the flexible substrate on a first pallet with the first side facing up. The method includes printing conductive adhesive to form first contact pads on the first side, placing at least one first component onto the first contact pads, and removing the flexible substrate from the first pallet. The method includes placing the flexible substrate on a second pallet with the second side facing up, where the second pallet includes recessed areas or cut outs that align with the at least one first component, printing conductive adhesive to form second contact pads on the second side, and placing at least one second component onto the second contact pads.

In another aspect, a double-sided flexible circuit assembly includes a flexible substrate with a first side and a second side opposite to the first side, a first conductive trace printed on the first side, and a second conductive trace printed on the second side. The double-sided flexible circuit assembly includes first contact pads formed by conductive adhesive printed on the first side, and second contact pads formed by conductive adhesive printed on the second side. The double-sided flexible circuit assembly includes at least one first component electrically coupled to the first contact pads, and at least one second component electrically coupled to the second contact pads.

### BRIEF DESCRIPTION OF THE DRAWINGS

The present application is illustrated by way of example and not limited in the accompanying figures in which like reference numerals indicate similar elements and in which:

FIG. 1 is a simplified side perspective drawing of an example double-sided flexible PCB;

FIG. 2 is a side perspective block diagram of an example double-sided flexible PCB and a pallet;

FIGS. 3A and 3B is a block diagram of an example method of creating a double-sided circuit assembly;

FIG. 4 is a block diagram of an example lighting device with a double sided-flexible PCB; and

FIG. 5 is a block diagram of an example sensor device with a double sided-flexible PCB.

### DETAILED DESCRIPTION

The detailed description that follows describes exemplary embodiments and the features disclosed are not intended to be limited to the expressly disclosed combination(s). Therefore, unless otherwise noted, features disclosed herein may be combined together to form additional combinations that were not otherwise shown for purposes of brevity.

The ability to attach components on both sides of a flexible printed circuit provides significant benefits, including reduced size boards with increased complexity. In addition, for flexible circuit boards that include light emitting devices (LEDs), the ability to attach the LEDs on both sides of the flexible substrate enables the generated light to shine forth from both sides.

The present disclosure provides, products and processes related to flexible printed circuit boards (PCB) with electronic components attached to both sides of the circuit board. The present disclosure also provides methods of fabricating such a double-sided flexible PCB. Additionally, the present disclosure provides devices using the double-sided flexible PCB.

Flexible printed circuit board (PCB) 100 mechanically supports and electrically connects electronic components using conductive tracks, pads and other features additively printed onto one or both sides of substrate 110. Components are generally attached onto the PCB to both electrically connect and mechanically fasten them to it using an electrically conductive adhesive. In some aspects, the electrically conductive adhesive includes solder, low temperature solder, conductive epoxy, anisotropic conductive adhesives, or the like. In some embodiments, the electrically conductive adhesive used to attach the components on a first side of substrate 110 is different from the conductive adhesive used to attach the components on a second side of substrate 110.

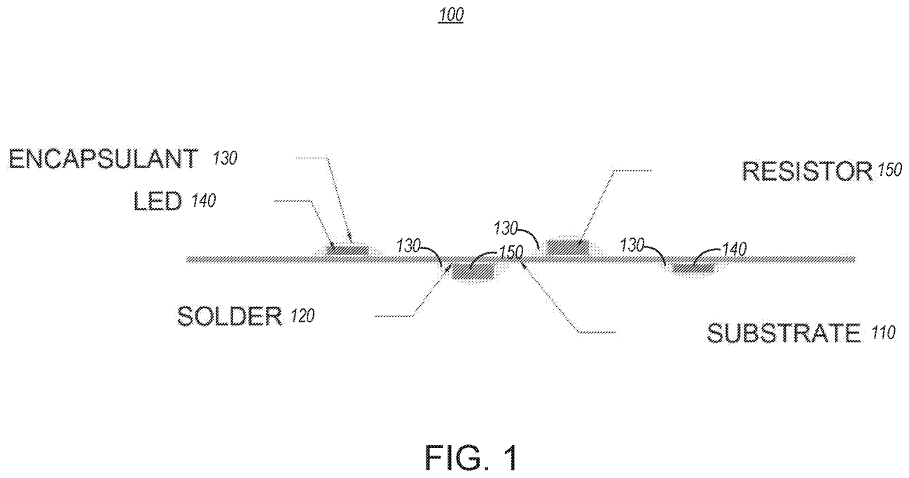

FIG. 1 is a simplified side perspective (cross-section) drawing of an example double-sided flexible PCB 100, according to the present invention. The double-sided flexible PCB 100 includes at least a substrate 110, conductive adhesive 120, components 140, 150, encapsulant 130, and conductive traces (not shown).

In an example aspect, the substrate is a flexible substrate comprised of flexible materials such as polymeric materials including but not limited to, polyethylene terephthalate film (PET), polyethylene naphthalate (PEN), polyimide foil (PI), polypropylene, polyethylene, polystyrene, polycarbonate, polyether ether ketone (PEEK), or any of a variety of polymer films or combinations thereof.

In an alternative aspect, the substrate includes portions that are rigid and comprise one or more of glass, wood, metal, PVC, silicon, epoxy resin, polycarbonate, or any of a variety of rigid materials or combinations thereof. In yet another aspect, the substrate includes a combination of one or more flexible materials described herein and one or more rigid materials described herein.

The conductive traces can be printed on to the substrate 110. In some aspects, the conductive traces comprise conductive material containing metallic particles such as, for example, but not limited to, silver, platinum, palladium, copper, nickel, gold, or aluminum or carbon or conductive polymer, or some combination thereof. In some aspects, the conductive traces include metallic particles and one or more chemical additives (e.g., solvents, binders, and the like) that improve one or more features of the conductive traces (e.g., flexibility stretchability, solderability, or the like). The conductive metals or composites can be flakes, fine particulates, or nano-particulates, or combinations thereof, in some embodiments

In some aspects, intricate patterns of the conductive traces can be selectively printed or otherwise deposited to form the circuit traces by any of a variety of printing or additive deposition methodologies, including, for example, any form of gravure, flatbed screen, flexography, lithography, screen, rotary screen, digital printing, inkjet printing, aerosol jet printing, 3-D printing, and like print methods, or combinations thereof.

In some aspects, the conductive material can be in the form of a printable conductive ink, toner, or other coating. The electronic inks can include non-conductive particles or particulates that are included to mechanically pierce or penetrate a native oxide formed on a metallic surface and thereby create a low-resistance electrical contact between the metallic surface and the electronic ink. In some such aspects, the non-conductive particles have a surface that includes features useful for piercing the oxidized metallic surface. In other aspects, the conductive particles have a surface that includes features useful for piercing the oxidized metallic surface. In some aspects, the ink includes solvents and/or binders to assist with removing or penetrating the native oxide layer to expose a non-oxidized aluminum surface.

In some aspects, silver ink is thermally cured, such that electrical testing after completion of the cure process provides a mechanically and low electrical resistance between the silver ink and metallic surface. In some other aspects, the present invention provides a fabrication process that includes printing silver ink directly onto an oxidized metallic surface to form a mechanically strong and electrically low-resistance interconnect to form an electrical circuit

In some aspects the components 140, 150 are attached to the substrate 110 using low temperature solder 120 or another such conductive adhesive. The components 140; 150 can comprise, for example, resistors, capacitors, inductors, transistors, flat no-leads packages, light emitting diodes (LED), microcontrollers, sensors, or connectors, etc. Any component, preferably of a relatively low profile form factor, can conceivably be attached to the substrate 110.

In some aspects, the encapsulant 130 is placed over the components 140, 150. The encapsulant 130 both protects, insulates, and mechanically secures the components 140, 150 on the substrate 110.

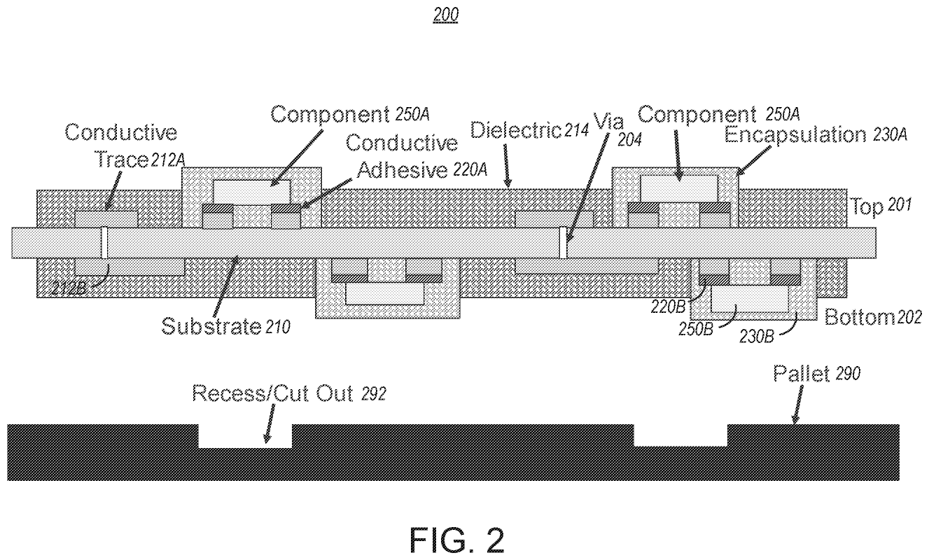

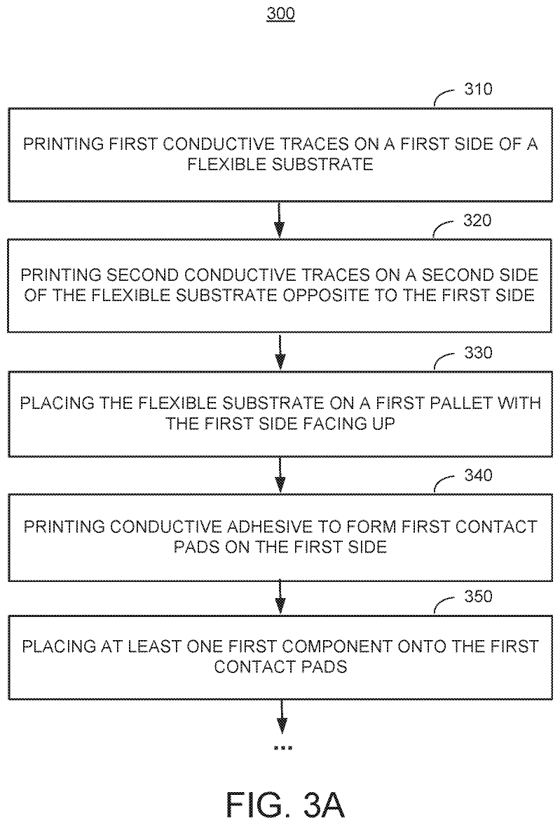

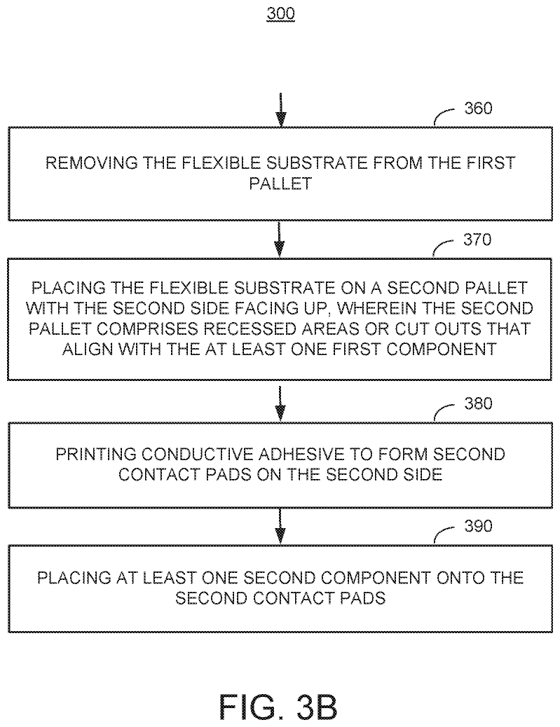

FIG. 2 is a side perspective block diagram of an example double-sided flexible PCB 210 and a pallet 290. In some aspects, conductive traces 212A, 212B, conductive adhesive 220A, 220B, dielectric 214, components 250A, 250B, and encapsulation 230A, 230B is attached to the substrate 210 in an example method described below in FIGS. 3A and 3B.

The double-sided flexible PCB 210 has a top side 201 and a bottom side 202 opposite the top side. The conductive traces 212A, conductive adhesive 220A, components 250A, and encapsulation 230A are attached to the top side 201 of the double-sided flexible PCB 210. The conductive traces 212B, conductive adhesive 220B, components 250B, and encapsulation 230B are attached to the bottom side 202 of the double-sided flexible PCB 210.

The pallet 290 includes recessed areas or cut outs that align with the components 250A on the top side 201 of the double-sided flexible PCB 210. The recessed areas of cut outs 292 of the second pallet 290 allows the flexible substrate 210 with the top side 201 facing down to lay flat on the second pallet 290.

FIGS. 3A and 3B is a block diagram of an example method 300 of creating a double-sided circuit assembly.

The method 300 at step 310 includes printing first conductive traces 212A on a first side 201 of a flexible substrate 210. In some aspects, the flexible substrate 210 is comprised of at least one of polyethylene terephthalate film (PET), polyethylene naphthalate (PEN), polyimide foil (PI), polyetherimide (PH), polypropylene, polyethylene, polystyrene, polycarbonate, or polyether ether ketone (PEEK) material.

The method 300 at step 320 includes printing second conductive traces 212B on a second side 202 of the flexible substrate 210 opposite to the first side 201. In some aspects, the conductive traces comprises 212A, 212B at least one of metallic particles of silver, platinum, palladium, copper, nickel, gold, or aluminum, or conductive polymer.

The method 300 optionally includes applying a dielectric coating 214 over the first conductive traces 212A and the second conductive traces 212B, wherein the dielectric coating 214 is not applied to areas where the at least one first component 250A and the at least one second component 250B is to be placed.

The method 300 optionally includes forming at least one least one vertical interconnect access (VIA) 201 in the flexible substrate 210. In printed circuit board design, a VIA commonly consists of two pads in corresponding positions on different layers of the board, that are electrically connected by a hole through the board. In some implementations, the hole is made conductive by electroplating, or is lined with a tube or a rivet.

The method 300 optionally includes filling the at least one VIA 201 with a conductive material.

The method 300 at step 330 includes placing the flexible substrate 210 on a first pallet (not shown) with the first side 201 facing up.

The method 300 at step 340 includes printing conductive adhesive to form first contact pads 220A on the first side 201.

The method 300 at step 350 includes placing at least one first component 250A onto the first contact pads 220A;

The method 300 at step 360 includes removing the flexible substrate 210 from the first pallet (not shown).

The method 300 at step 370 includes placing the flexible substrate 210 on a second pallet 290 with the second side facing up 202, wherein the second pallet 290 comprises recessed areas or cut outs 292 that align with the at least one first component 250A. The recessed areas of cut outs 292 of the second pallet 290 allows the flexible substrate 210 to lay flat on the second pallet 290.

The method 300 step 380 includes printing conductive adhesive to form second contact pads 220B on the second side 202.

The method 300 at step 390 includes placing at least one second component 250B onto the second contact pads 220B. In some aspects, the at least one first component 250A and the at least one second component 250B comprises at least one resistor, capacitor, inductor, transistor, flat no-leads package, light emitting diode (LED), microcontroller, sensor, or connector

The method 300 optionally includes applying an encapsulation material over the at least one first component 250A and/or over the at least one second component 250B.

In an example implementation, the double-sided flexible PCB is part of a display device having a first display on a first surface and a second display on a second surface opposite the first surface, wherein components on one side of the flexible PCB provides illumination for the first display and components on a second side of the flexible PCB provides illumination for the second display.

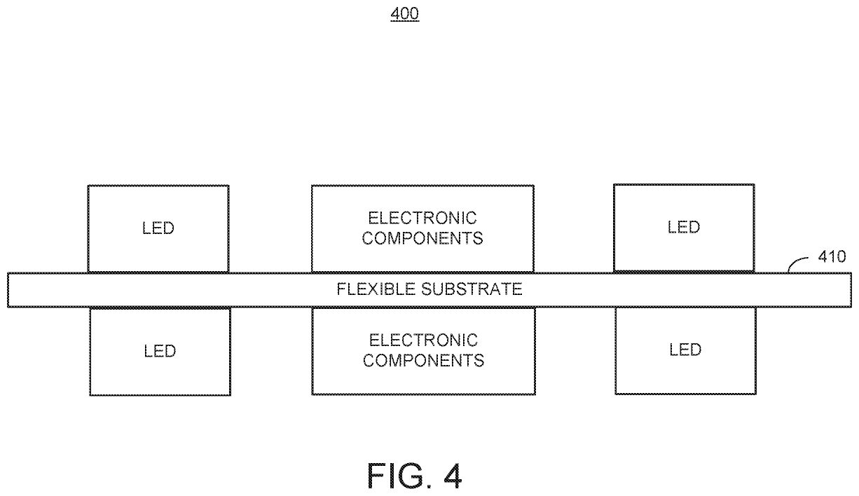

FIG. 4 is a block diagram of an example lighting device 400 with a double sided-flexible PCB. In an example implementation, a lighting device can include the double-sided flexible PCB with LEDs on both sides in addition to other electrical components such as resistors, capacitors, inductors, microcontrollers, etc. The lighting device enables simultaneous “up” and “down” lighting in a thin and flexible format. The lighting device enables simultaneous lighting of two sides of a flat or curved object.

In an example implementation, a display device can include the double-sided flexible PCB with display screens on both sides. For example, the display device can be a laptop computer screen with secondary screen on outside of lid. In another example, the display device can be a tablet with secondary screen or lighting on exterior or side opposite the display.

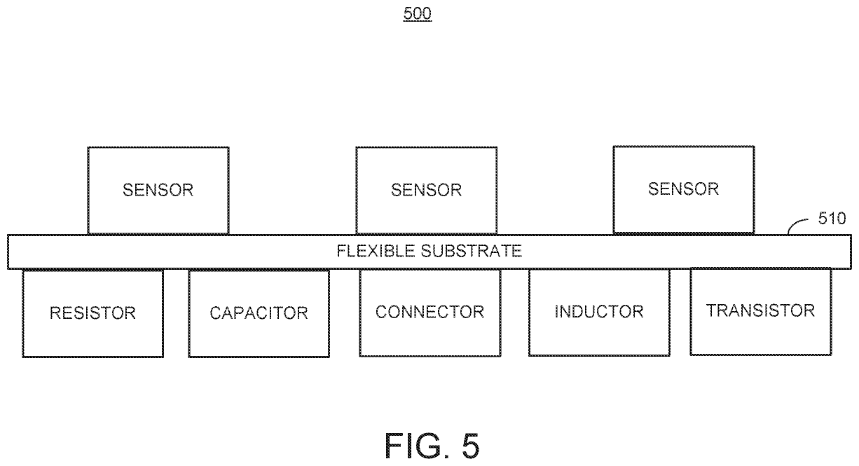

FIG. 5 is a block diagram of an example sensor device 500 with a double sided-flexible PCB. In an example implementation, the double-sided flexible PCB is part of a wearable sensor device. For example the components on a first side or second side of the flexible PCB comprises at least one temperature sensor, electrode, galvanic resistance sensor, humidity sensor, biomarker sensor, or sweat sensor.

In an example implementation, a wearable body patch can include the double-sided flexible PCB with the sensor(s) on only one side of the wearable body patch and all the other electrical components are on the other side of the wearable body patch. For example, the sensors on one side wearable body patch can include one or more temp sensors, electrodes, galvanic resistance sensors (e.g., measuring galvanic skin resistance), humidity sensors, biomarker sensors, sweat sensors, etc. The wearable body patch with sensors only on the side facing a user's skin allows improved or more accurate measurements of body markers. In addition, the wearable body patch including electronics only on the side opposite the skin improves comfort of the user.

In an example implementation, the double-sided flexible PCB is part of an electronic label device. For example, the at least one component on one side of the flexible PCB comprises at least one sensor and the at least one component on a second side of the flexible PCB comprises at least one transistor, flat no-leads package, light emitting diode (LED), microcontroller, or connector.

In an example implementation, the double-sided flexible PCB is part of an electronic label/tag with sensing capabilities where the sensor(s) are only on one side of the label while all the other electrical components are on the other side of the label. For example, the double-sided flexible PCB includes temperature sensors only on a first side and non-sensor components only on a second side opposite the first side.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A method for creating a circuit assembly, comprising:
printing first conductive traces on a first side of a flexible substrate;
printing second conductive traces on a second side of the flexible substrate opposite to the first side;
placing the flexible substrate on a first pallet with the first side facing up;
printing conductive adhesive to form first contact pads on the first side;
placing at least one first component onto the first contact pads;
removing the flexible substrate from the first pallet;
placing the flexible substrate on a second pallet with the second side facing up, wherein the second pallet includes recessed areas or cut outs that align with the at least one first component;
printing conductive adhesive to form second contact pads on the second side; and
placing at least one second component onto the second contact pads.

2. The method of claim 1, further comprising forming at least one vertical interconnect access (VIA) in the flexible substrate.

3. The method of claim 2, further comprising connecting the first conductive aces to the second conductive traces with the at least one VIA.

4. The method of claim 2, further comprising filling the at least one VIA with conductive material.

5. The method of claim 1, wherein the flexible substrate is comprised of at least one of polyethylene terephthalate film (PET), polyethylene naphthalate (PEN), polyimide foil (PI), polyetherimide (PEI), polypropylene, polyethylene, polystyrene, polycarbonate, or polyether ether ketone (PEEK) material.

6. The method of claim 1, wherein the conductive traces comprises at least one of metallic particles of silver, platinum, palladium, copper, nickel, gold, or aluminum, or conductive polymer.

7. The method of claim 1, further comprising applying a dielectric coating over the first conductive traces and the second conductive traces, wherein the dielectric coating is not applied to areas where the at least one first component and the at least one second component is to be placed.

8. The method of claim 1, further comprising applying an encapsulation material over the at least one first component.

9. The method of claim 1, further comprising applying an encapsulation material over the at least one second component.

10. The method of claim 1, wherein the at least one first component and the at least one second component comprises at least one resistor, capacitor, inductor; transistor, flat no-leads package, light emitting diode (LED), microcontroller, sensor, or connector.

11. A double-sided flexible circuit assembly comprising:
a flexible substrate with a first side and a second side opposite to the first side;
a first conductive trace printed on the first side;
a second conductive trace printed on the second side;
first contact pads formed by conductive adhesive printed on the first side;
second contact pads formed by conductive adhesive printed on the second side;
at least one first component electrically coupled to the first contact pads; and
at least one second component electrically coupled to the second contact pads.

12. The double-sided flexible circuit assembly of claim 11, wherein the at least one first component and the at least one second component comprises at least one resistor, capacitor, inductor, transistor, flat no-leads package, light emitting diode (LED), microcontroller, sensor, or connector.

13. The double-sided flexible circuit assembly of claim 12, wherein each of the at least one first component and the at least one second component comprises at least one light emitting diode (LED).

14. The double-sided flexible circuit assembly of claim 11, wherein the flexible substrate is part of a display device having a first display on a first surface and a second display on a second surface opposite the first surface, wherein the at least one first component provides illumination for the first display and the at least one second component provides illumination for the second display.

15. The double-sided flexible circuit assembly of claim 11, wherein the flexible substrate is part of a wearable sensor device and including only sensors on one of the first side or the second side and only non-sensor electronics on an opposite side.

16. The double-sided flexible circuit assembly of claim 15, wherein the sensors comprises at least one temperature sensor, electrode, galvanic resistance sensor, humidity sensor, biomarker sensor, or sweat sensor.

17. The double-sided flexible circuit assembly of claim 11, wherein the flexible substrate is part of an electronic label device and including only sensors on one of the first side or the second side and only non-sensor electronics on an opposite side.

18. The double-sided flexible circuit assembly of claim 17, wherein the at least one first component comprises at least one sensor and the at least one second component comprises at least one transistor, flat no-leads package, light emitting diode (LED), microcontroller, or connector.
